(19) United States
(12) Patent Application Publication
(10) Pub. No.: US 2023/0361532 A1
(43) Pub. Date: Nov. 9, 2023

(54) SILICON PHOTONIC HYBRID DISTRIBUTED FEEDBACK LASER WITH BUILT-IN GRATING

(71) Applicant: OpenLight Photonics, Inc., Goleta, CA (US)

(72) Inventors: Hanxing Shi, Mountain View, CA (US); Antonio Labaro, Sunnyvale, CA (US); Erik Johan Norberg, Santa Barbara, CA (US); Han Yun, Santa Clara, CA (US)

(21) Appl. No.: 17/736,490

(22) Filed: May 4, 2022

(51) Int. Cl. H01S 5/12; H01S 5/026

(52) U.S. Cl. CPC H01S 5/1231; H01S 5/0265; H01S 5/124

(57) ABSTRACT

A hybrid distributed feedback (DFB) laser formed from III-V and silicon materials can include a grating in the III-V material to provide optical feedback for mode selection. The grating can include a shift feature in a middle or other parts of the grating to change light output from the gain region. The grating can be a top-surface grating or regrowth can be applied to the III-V structure, which can then be bonded to a silicon structure to couple DFB laser light from the III-V structure to one or more silicon waveguides in the silicon structure.

### TECHNICAL FIELD

The present disclosure generally relates to optical devices and more particularly to optical sources.

### BACKGROUND

A tunable laser is a laser in which the wavelength of operation can be altered in a controlled manner using filters to output the target wavelength. The tuning values vary over temperature and can require complex control systems to keep the tunable laser aligned during operation. A fixed laser is simpler to control; however, it is difficult to implement fixed lasers in photonic integrated circuits (PICs) due to calibration issues, power issues, and process control issues, such as process variation exhibited in modern PIC fabrication techniques.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, or characteristic included in at least one implementation of the inventive subject matter. Thus, phrases such as “in one embodiment” or “in an alternate embodiment” appearing herein describe various embodiments and implementations of the inventive subject matter, and do not necessarily all refer to the same embodiment. However, they are also not necessarily mutually exclusive. To easily identify the discussion of any particular element or act, the most significant digit or digits in a reference number refer to the figure (“FIG.”) number in which that element or act is first introduced.

FIG. 1 shows a silicon based distributed feedback (DFB) laser architecture, according to some example embodiments.

FIG. 2 shows an example multi-lane silicon fabricated low-loss DFB laser architecture, according to some example embodiments.

FIG. 3 shows an example a multi-lane silicon fabricated low-loss DFB architecture in which each symmetric DFB laser drives two lanes of a multi-lane architecture, according to some example embodiments.

FIG. 4 shows example DFB laser architectures that implement a Mach-Zehnder Modulator (MZM) for power combining, in accordance with some example embodiments.

FIG. 5 shows an example method for implementing a symmetric DFB device, according to some example embodiments.

FIG. 6 shows a flow diagram of a method for calibration of a symmetric DFB optical device, according to some example embodiments.

FIG. 7 shows an example optical transceiver, according to some example embodiments.

FIG. 8 is a diagram showing a side view of an optical-electrical device, according to some example embodiments.

FIGS. 9A and 9B show an approach for fabricating one or more symmetric DFB lasers having III-V gratings, according to some example embodiments.

FIG. 10A shows an example DFB laser with integrated III-V gratings, in accordance with some example embodiments.

FIG. 10B shows the example DFB laser with integrated III-V gratings, in accordance with some example embodiments.

FIG. 10C shows an example asymmetric DFB laser, in accordance with some example embodiments.

FIG. 11 shows a flow diagram of a method for implementing a DFB laser having integrated III-V gratings, in accordance with some example embodiments.

FIG. 12 shows a flow diagram of a method 1200 for forming a DFB laser having integrated III-V gratings, in accordance with some example embodiments.

Descriptions of certain details and implementations follow, including a description of the figures, which may depict some or all of the embodiments described below, as well as discussing other potential embodiments or implementations of the inventive concepts presented herein. An overview of embodiments of the disclosure is provided below, followed by a more detailed description with reference to the drawings.

### DETAILED DESCRIPTION

In the following description, for the purposes of explanation, numerous specific details are set forth in order to provide an understanding of various embodiments of the inventive subject matter. It will be evident, however, to those skilled in the art, that embodiments of the inventive subject matter may be practiced without these specific details. In general, well-known instruction instances, structures, and techniques are not necessarily shown in detail.

As discussed, a PIC can implement a tunable laser, in which the laser can be tuned to output light of different wavelengths. In some example embodiments, the tunable laser can implement one or more optical filters to obtain a target wavelength of the optical system. The tuning values can vary over different temperatures, which can necessitate fast control loops that are integrated close to the PIC to ensure the tuners are aligned during operation. A fixed wavelength (e.g., single mode) silicon photonic laser with DFB can be configured in the PIC such that no wavelength calibration is required, which can reduce calibration cost and can further allow faster module bootup time, thereby reducing power consumption and simplifying laser control. A DFB laser can be implemented as an integrated PIC laser in which the laser resonator comprises of a periodic structure in the laser gain medium, which functions as a distributed Bragg reflector in the wavelength range of laser action. In some example embodiments, a distributed-feedback laser has multiple axial resonator modes, but there is typically one mode which is preferable in terms of losses; thus, single-frequency operation can be implemented.

While some non-silicon based DFB sources can implement facet coatings (e.g., anti-reflectivity (AR) coating, high-reflectivity (HR) coating) to obtain higher power, this approach is incompatible with silicon based photonic DFBs because coatings cannot be applied to facets of a silicon based photonic DFB. Additionally, these approaches waste power as the coatings have defects which can waste portions of the light (e.g., 20%). Additionally, these approaches suffer from reliability issues due the coatings. Additionally, these approaches exhibit poor feedback tolerance and are more sensitive to feedback and reflections. Additionally, applying the coating requires access to both the DFB output sides to apply the coatings, and coatings cannot be applied to silicon designs having integrated sources that are integrated in the middle the design, thereby making such access impossible.

To address the foregoing, a silicon photonic symmetric DFB can be implemented to provide light to the PIC in an approach that has a similar power efficiency as non-silicon photonic DFBs by forming a grating in the III-V layer, and by utilizing power from one output or both outputs of the silicon photonic symmetric DFB.

The bends in the routing of the silicon photonic symmetric DFB can be configured such that they are low loss and without reflection to the silicon photonic symmetric DFB, in contrast to bends of III-V based DFBs that cause high loss and high reflection and thus cannot be used to implement symmetric DFBs. In fiber based DFBs, large and expensive components are required to adjust and stabilize the phase of both outputs to combine them in a 2×1 coupler. The large size of fiber based DFB laser prevents their use in typical multiple lane transceivers such as ethernet applications (e.g., a multiple lane transceiver in which both laser outputs are utilized, such as combined for a single lane or each output running a separate lane).

In some example embodiments, a silicon photonic symmetric DFB is configured such that no wavelength adjustment is required in operation, which increases the power efficiency while achieving high optical mode stability. In some example embodiments, the silicon photonic symmetric DFB outputs to two waveguides and couples the light using a 2×1 optical combiner, in which the waveguides are fully symmetric waveguides to reduce phase errors, and thermal phase tuners provide optical phase matching at the input to the 2×1 optical combiner which outputs the optical beam. In some example embodiments, the silicon photonic symmetric DFB outputs to two different waveguides which drive separate optical lanes with the same operating wavelength, which achieves high power efficiency due to the optical power from both output ports being used.

One additional challenge is that while gratings can be fabricated in silicon (e.g., in a silicon waveguide), this type of processing requires specialized equipment and design processes that may be not be practical in some manufacturing environments. To this end, in some example embodiments, a grating is formed in the III-V structure and is then bonded to the silicon structure, as discussed in further detail below.

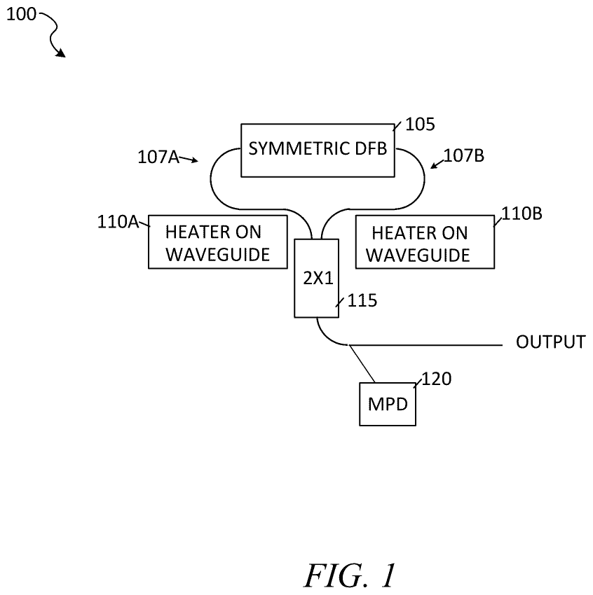

FIG. 1 shows a silicon based DFB laser architecture 100, according to some example embodiments. In the example of FIG. 1, a silicon based DFB laser 105 has symmetric gratings and a symmetric cavity design. In some example embodiments, each of the gratings has a coupling constant (kappa) that is symmetric around a center or can vary (e.g., periodically) across the length of the DFB. The light is output from both sides of the silicon based DFB laser 105 into output waveguides, including a first waveguide 107A and a second waveguide 107B. The light output to the waveguides is not perfectly in phase (e.g., due to manufacturing variations) and can be phase adjusted using heaters, such as heater 110A and heater 110B (e.g., resistive metal on top of a given waveguide). In some example embodiments, the waveguides are coiled under their respective heaters via s-bends in the silicon architecture such that the heater power can be reduced. The light from the first waveguide 107A and second waveguide 107B is then combined in a coupler 115 (e.g., multimode interference (MMI) coupler, directional coupler, Y-junction coupler). In some example embodiments, a portion of the output from the coupler 115 is tapped into a monitor photodiode 120 for measuring the power levels for calibration and operation, as discussed in further detail below.

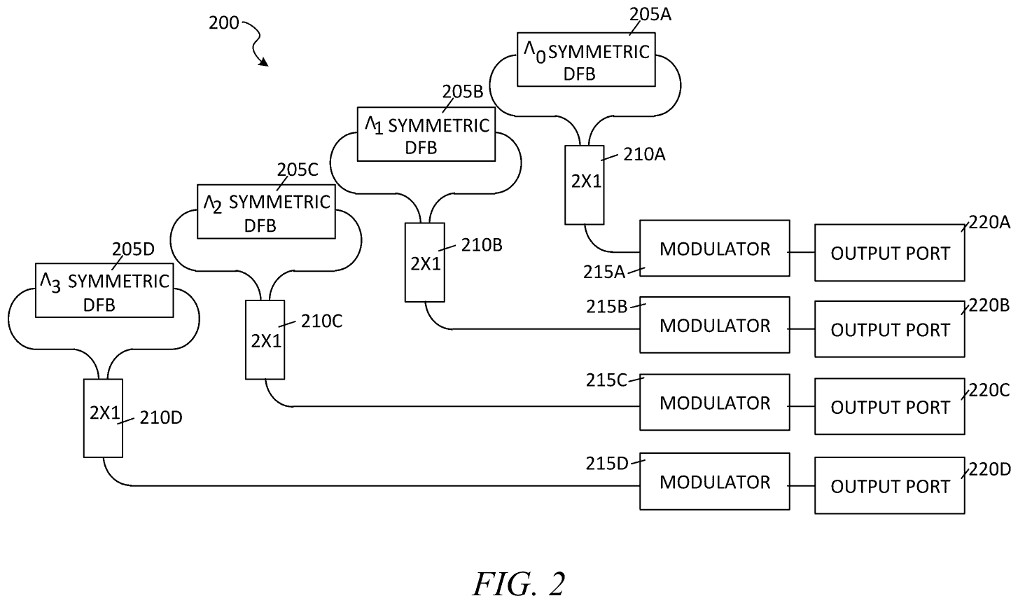

FIG. 2 shows a multi-lane silicon based DFB laser architecture 200, according to some example embodiments. The multi-lane silicon based DFB laser architecture 200 is an example of a coarse wavelength division multiplexing (CWDM) transmitter architecture (e.g., 400G-FR4 application) that can be integrated in a multi-lane transceiver PIC (e.g., 700). As illustrated, the first symmetric DFB laser 205A (e.g., set to a first wavelength) outputs to a coupler 210A, which combines the light, which is then modulated by the modulator 215A (e.g., electroabsorption modulator) and output via an output port 220A. In the example of FIG. 2, the heaters are omitted for clarity in FIG. 2.

Continuing, the second symmetric DFB laser 205B (e.g., set to a second wavelength that is higher than the first wavelength) outputs to a coupler 210B, which combines the light, which is then modulated by the modulator 215B and output via an output port 220B. Further, the third symmetric DFB laser 205C (e.g., set to a third wavelength that is higher than the second wavelength) outputs to a coupler 210C, which combines the light, which is then modulated by the modulator 215C and output via an output port 220C. Further, the fourth symmetric DFB laser 205D (e.g., set to a fourth wavelength that is higher than the third wavelength) outputs to a coupler 210D, which combines the light, which is then modulated by the modulator 215D and output via an output port 220D.

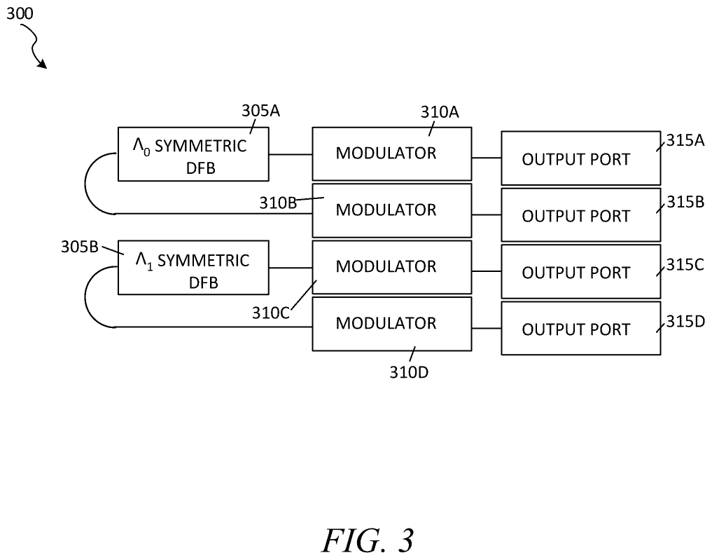

FIG. 3 shows an example a multi-lane silicon based DFB architecture 300 in which each symmetric DFB drives two lanes of a multi-lane architecture, according to some example embodiments. In particular, one side of the silicon photonic integrated symmetric DFB laser 305A can provide light of a given wavelength (e.g., θ₀) for a first lane in which the light is modulated by a modulator 310A and then output via output port 315A, where the components are coupled via low-loss integrated silicon waveguides all fabricated together. Further, the other side of the silicon photonic integrated symmetric DFB laser 305A provides light of the given wavelength (e.g., Λ₀) for a second lane, where the light is modulated by a modulator 310B and then output via output port 315B, where the first and second lanes receive half of the light power provided by the silicon photonic integrated symmetric DFB laser 305A.

Similarly, for the third and fourth lanes, one side of the silicon photonic integrated symmetric DFB laser 305B can provide light of a given wavelength (e.g., Ai) for a third lane in which the light is modulated by a modulator 310C and then output via output port 315C. Further, the other side of the silicon photonic integrated symmetric DFB laser 305B provides light of the given wavelength (e.g., Ai) for a fourth lane, where the light is modulated by a modulator 310D and then output via output port 315D, where the third and fourth lanes receive half of the light power provided by the silicon photonic integrated symmetric DFB laser 305B. In some example embodiments, the multi-lane silicon based DFB architecture 300 does not include heaters, and the light emanating from either side of the silicon photonic integrated symmetric DFB laser 305A may be out of phase, but the light from the different sides are not combined (e.g., in a 2×1 coupler as in FIG. 1 and FIG. 2). In some example embodiments, the multi-lane silicon based DFB architecture 300 is a low power design in which the 305A and 305D are each 10 mW silicon DFBs and DFBs in which the symmetric DFB outputs are combined are higher power designs in which the symmetric DFBs are each 20 mW silicon based DFBs.

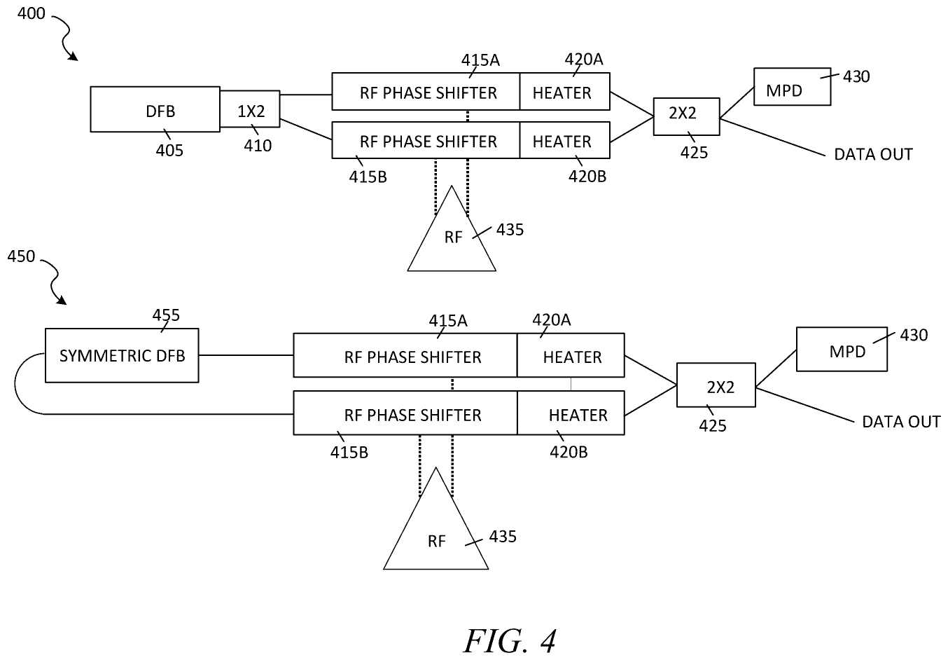

FIG. 4 shows example symmetric DFB architectures that implement a Mach-Zehnder Modulator (MZM) for power combining, in accordance with some example embodiments. A Mach-Zehnder modulator is an interferometric structure made from a material with an electro-optic effect (e.g., LiNbO3, GaAs, InP), in which electric fields are applied to the arms to change the optical path lengths, thereby resulting in phase modulation. In some example embodiments, combining two arms (e.g., via a 2×2 coupler) with different phase modulation converts phase modulation into intensity modulation. In the example architecture 400, a DFB 405 generates light that is split via a 1×2 coupler 410 into the upper and lower modulator arms. A radio frequency (RF) source 435 controls one or more phase shifters to implement modulation, such as an RF phase shifter 415A and an RF phase shifter 415B. Further, a heater 420A and heater 420B are implemented to compensate for phase imbalance in the arms. In some example embodiments, one of the heaters is activated to phase balance the arms to hold the MZM at the correct bias point for a differential high-speed signal applied to the RF phase shifters 415A and 415B to modulate the signal. The modulated light is then combined via a 2×2 coupler 425 and then output to a data output port and a monitor photodiode 430 for calibration and monitoring of the device.

The architecture 450 illustrates a low loss approach in which the 1×2 coupler 410 is omitted and instead a symmetric DFB 455 provides light for both lanes, as discussed above with reference to FIG. 3. In some example embodiments, the coupler 2×2 425 is also omitted from the silicon design and instead bias control is managed by an MZM bias control unit.

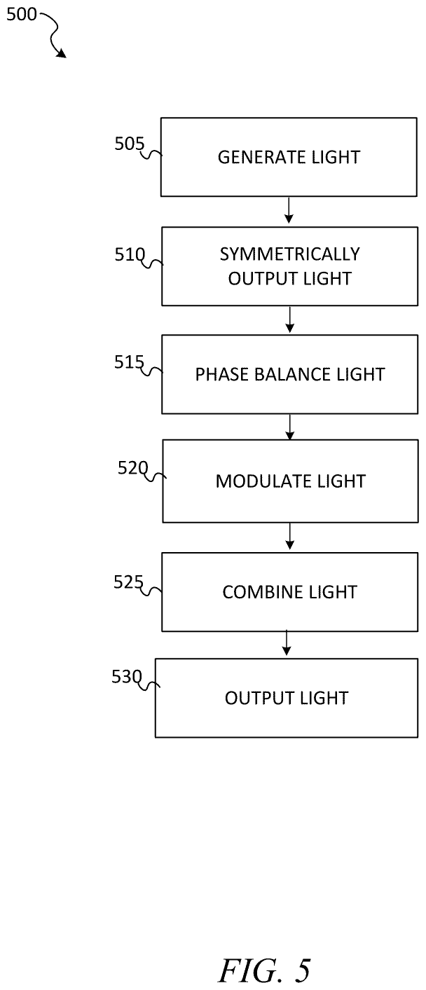

FIG. 5 shows a flow diagram of an example method 500 for implementing an optical device having one or more silicon fabricated low-loss symmetric DFB lasers that are fabricated with other components of the optical device in a PIC (e.g., waveguides, couplers), according to some example embodiments. At operation 505, a symmetric DFB laser generates light. For example, the silicon based DFB laser 105 generates light at a target wavelength. At operation 510, the generated light is symmetrically output from the symmetric DFB. For example, half of the generated light is output from one side of the DFB and the other half of the light is output from the other side of the symmetric DFB onto silicon waveguides. At operation 515, the light in the waveguides is phase balanced. For example, the light exiting from the opposite sides of the symmetric DFB are slightly out of phase due to fabrication variations (e.g., process variation), and one of the heaters (e.g., heater 110A, heater 110B) is activated to phase balance light in one of the waveguides. In some example embodiments, the symmetrically output light is output to different lanes of the transmitter and the heaters are omitted and operation 515 is skipped.

At operation 520, the light is combined. For example, with reference to FIG. 2, the phase corrected light is combined using a coupler 210A. In some example embodiments, the light is not combined and the output from each side of the symmetric DFB is output to different lanes and operation 520 is omitted.

At operation 525, the light is modulated. For example, the modulator 215A modulates light of the first lane, which is light from both sides of the first symmetric DFB laser 205A which is combined via coupler 210A. As an additional example, the modulator 310A in FIG. 3 modulates light that is output from one of the sides of the silicon photonic integrated symmetric DFB laser 305A.

At operation 530, the light is output from the device. For example, the each lane of light is output from respective output ports (e.g., output ports 220A-220D of FIG. 2, output ports 315A-315D of FIG. 3).

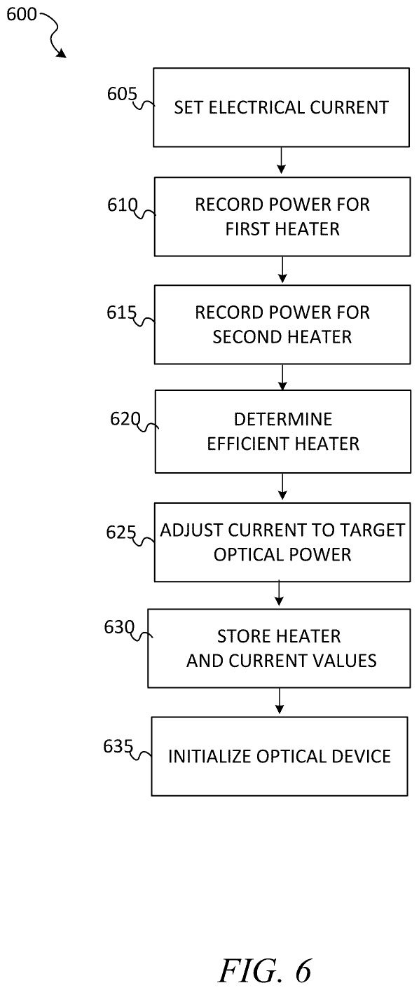

FIG. 6 shows a flow diagram of a method 600 for calibration of a symmetric DFB optical device, according to some example embodiments. An advantage of heater based architecture (e.g., silicon based DFB laser architecture 100) is that phase imbalance from the silicon based DFB laser 105 between the two arms can be compensated for after fabrication, and the phase adjustment requires only monitoring the optical tap power at the monitor photodiode 120.

In some example embodiments, heaters are added on both sides (e.g., heater 110A, heater 110B) but only one is used at a given time to compensate for small positive or negative phase imbalance, due to process variation in fabrication of the PIC having the symmetric DFBs. At operation 605, the electrical current for the symmetric DFB laser (e.g., silicon based DFB laser 105) is set to a nominal value (e.g., 100 milliamps). At operation 610, the maximum power for one of the heaters is recorded. For example, the power of the heater 110A is swept while the value of the monitor photodiode 120 is monitored, and the power value for the heater 110A is recorded when the monitor photodiode (MPD) reading is maximized.

At operation 615, the maximum power for another of the heaters is recorded. For example, the power of the heater 110B is swept while the value of the monitor photodiode 120 is monitored, and the power value for the heater 110B is recorded when the MPD reading is maximized.

At operation 620, it is determined whether heater 110A or heater 110B is more efficient (e.g., which has less power usage at maximum MPD reading) when the MPD reading is maximized, and heater power is applied to the most efficient of the heaters to phase balance the arms.

At operation 625, the electrical current of the symmetric DFB is adjusted until the target optical power is reached on MPD. At operation 630, the heater values and electrical current settings are saved to memory (e.g., flash memory) of the optical system (e.g., optical transceiver 700) to be implemented when the system is initialized for operation. In some example embodiments, the method 600 is performed multiple times for additional DFBs in the device (e.g., DFBs 205A-205D), and the respective values for each lane are stored at operation 630.

At operation 635, the optical system having the one or more symmetric DFBs is initialized for operation (e.g., in the field, in a product) and the stored values are applied to the one or more symmetric DFBs and one or more heaters for efficient operation of the optical device.

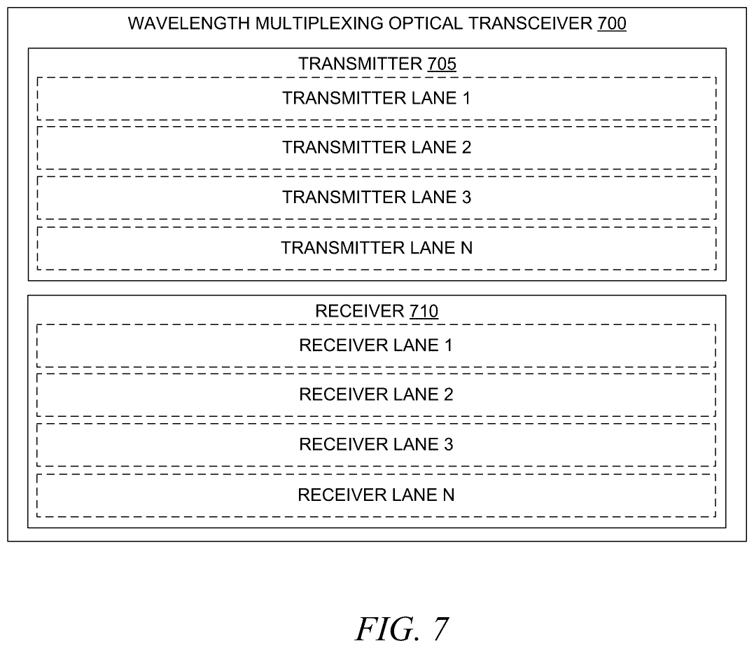

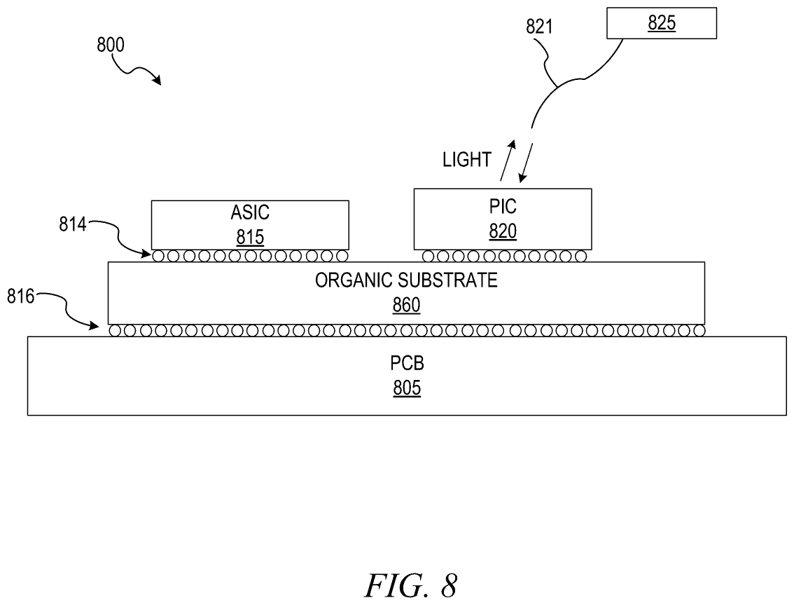

FIG. 7 shows a multi-lane wavelength division multiplexing optical transceiver 700, according to some example embodiments. In the illustrated embodiment, the optical transceiver 700 comprises an integrated photonic transmitter structure 705 and an integrated photonic receiver structure 710. In some example embodiments, the integrated photonic transmitter structure 705 and the integrated photonic receiver structure 710 are example optical components fabricated as a PIC device, such as PIC 820 of FIG. 8, discussed below. The integrated photonic transmitter structure 705 is an example of a dense wavelength division multiplexing (DWDM) transmitter having a plurality of lanes (transmitter lanes 1-N) in which each lane handles a different wavelength of light. The integrated photonic receiver structure 710 is an example of a DWDM receiver that receives DWDM light (e.g., from an optical network or from the integrated photonic transmitter structure 705 in loopback mode). The integrated photonic receiver structure 710 can receive and process light by filtering, amplifying, and converting it to electrical signal using components such as multiplexers, semiconductor optical amplifiers (SOAs), and one or more detectors such as photodetectors (e.g., photodiodes).

FIG. 8 shows a side view of an optical-electrical device 800 including one or more optical devices, according to some example embodiments. In illustrated embodiment, the optical-electrical device 800 is shown to include a printed circuit board (PCB) substrate 805, organic substrate 860, an application-specific integrated circuit 815 (ASIC), and PIC 820.

In some example embodiments, the PIC 820 includes silicon on insulator (SOI) or silicon based (e.g., silicon nitride (SiN)) devices, or may comprise devices formed from both silicon and a non-silicon material. Said non-silicon material (alternatively referred to as “heterogeneous material”) may comprise one of III-V material, magneto-optic (MO) material, or crystal substrate material. III-V semiconductors have elements that are found in group III and group V of the periodic table (e.g., Indium Gallium Arsenide Phosphide (InGaAsP), Gallium Indium Arsenide Nitride (GainAsN), Aluminum Indium Gallium Arsenide (AlInGaAs)). The carrier dispersion effects of III-V-based materials may be significantly higher than in silicon-based materials, as electron speed in III-V semiconductors is much faster than that in silicon. In addition, III-V materials have a direct bandgap, which enables efficient creation of light from electrical pumping. Thus, III-V semiconductor materials enable photonic operations with an increased efficiency over silicon for both generating light and modulating the refractive index of light. Thus, III-V semiconductor materials enable photonic operation with an increased efficiency at generating light from electricity and converting light back into electricity.

The low optical loss and high quality oxides of silicon are thus combined with the electro-optic efficiency of III-V semiconductors in the heterogeneous optical devices described below; in embodiments of the disclosure, said heterogeneous devices utilize low loss heterogeneous optical waveguide transitions between the devices' heterogeneous and silicon-only waveguides.

MO materials allow heterogeneous PICs to operate based on the MO effect. Such devices may utilize the Faraday Effect, in which the magnetic field associated with an electrical signal modulates an optical beam, offering high bandwidth modulation, and rotates the electric field of the optical mode, enabling optical isolators. Said MO materials may comprise, for example, materials such as iron, cobalt, or yttrium iron garnet (YIG). Further, in some example embodiments, crystal substrate materials provide heterogeneous PICs with a high electro-mechanical coupling, linear electro-optic coefficient, low transmission loss, and stable physical and chemical properties. Said crystal substrate materials may comprise, for example, lithium niobate (LiNbO3) or lithium tantalate (LiTaO3).

In the example illustrated, the PIC 820 exchanges light with an external light source 825 via an optical fiber 821, in a flip-chip configuration where a top-side of the PIC 820 is connected to the organic substrate 860 and light propagates out (or in) from a bottom-side of the PIC 820 facing away (e.g., towards a coupler), according to some example embodiments. The optical fiber 821 can couple with the PIC 820 using a prism, grating, or lens, according to some example embodiments. The optical components of PIC 820 (e.g., optical modulators, optical switches) are controlled, at least in part, by control circuitry included in ASIC 815. Both ASIC 815 and PIC 820 are shown to be disposed on copper pillars 814, which are used for communicatively coupling the PICs via organic substrate 860. PCB substrate 805 is coupled to organic substrate 860 via ball grid array (BGA) interconnect 816 and may be used to interconnect the organic substrate 860 (and thus, ASIC 815 and PIC 820) to other components of the optical-electrical device 800 not shown (e.g., interconnection modules, power supplies, etc.).

As discussed above, while DFB lasers can have gratings fabricated in the silicon waveguide, the processing uses specialized lithography equipment to generate a grating pattern with sufficiently small dimensions. Unfortunately, silicon foundries may not have lithography capabilities for grating fabrication and generally it requires heavy capital investment in further equipment (e.g., deep UV lithography equipment). Further, development time of the Si grating process can be significant, and the poor repeatability of the process is still problematic. Further, moving production wafers out of the Si foundry to do the grating step elsewhere increases cycle time and risk contamination.

In some example embodiments, the gratings are formed in the III-V structure using III-V epitaxy growth, and optionally regrowth. In some example embodiments, the III-V epitaxial structure is first half-way grown, then grating is patterned and etched, and the laser structure is finished by regrowth to embed the grating inside the materials. In some example embodiments, the III-V is grown to specification and a top-surface grating is etched and no regrowth occurs (e.g., the III-V epi die is flip-chip bonded to the SOI using the top-surface such that the mode is adiabatically coupled to the silicon waveguides in the SOI). One advantage of forming DFB gratings in the III-V structure is that it parallelizes manufacturing processes between the foundries: for example, between a III-V manufacturing facility that produces the III-V grating structure in parallel with a silicon wafer manufacturing facility to completes the silicon wafer front end processing. Further, a DFB with the grating in the III-V structure avoids extra process steps in the Silicon foundry beyond the existing SiPh process flow (e.g., used to design the silicon wafer). In this way, many Si foundries can more readily be used to manufacturing a DFB laser with wafer bonding processes. For instance, a given SiPh foundry may be configured for 500 nm Silicon thickness in the SOI wafer, while other SiPh foundries may be configured for a 220 nm Silicon thickness; however, it can be difficult or not possible to form gratings in when the Silicon is as thin as 220 nm. As such, forming the grating in III-V structure enables the design and fabrication processes to become insensitive to SOI thickness, which allows us to implement this concept to any SOI structure including 220 nm Si.

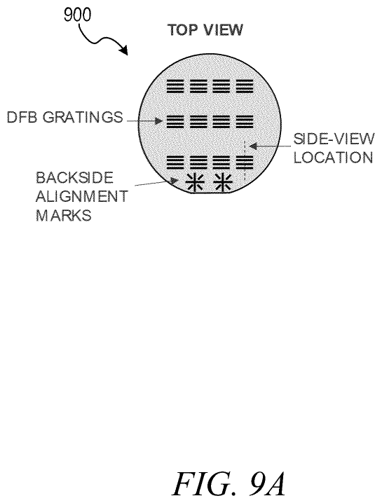

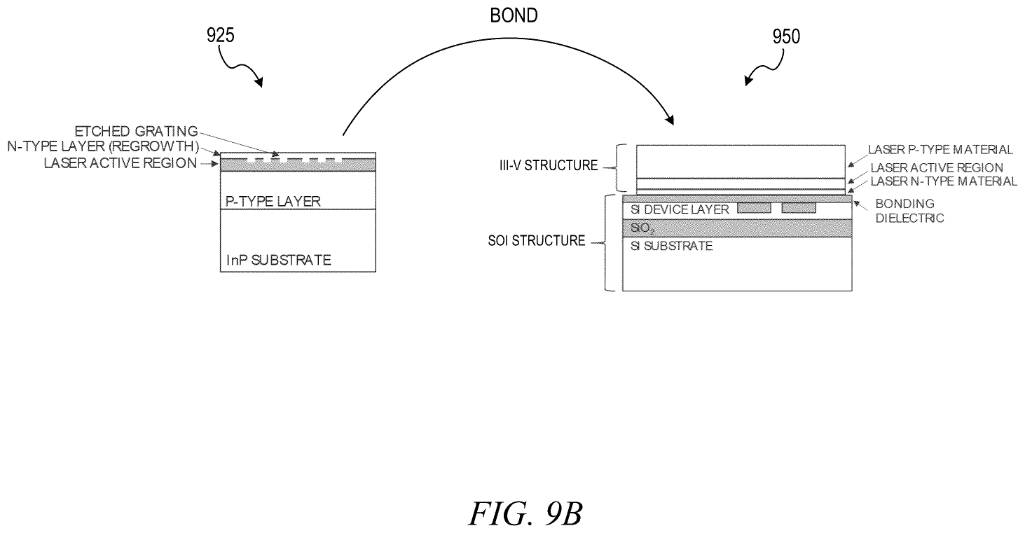

FIGS. 9A and 9B show an approach for forming one or more symmetric DFB lasers having vertical III-V gratings, according to some example embodiments. In FIG. 9A, a III-V structure 900 is partially grown. For example, a III-V wafer comprising one or more layers of InP, GaAs, AlAs, or InAs is partially grown (e.g., grown using III-V epitaxy growth manufacturing processing). In some example embodiments, DFB gratings are then patterned on the III-V structure (e.g. using nano-imprint or electron-beam lithography). In some example embodiments, after the DFB gratings are patterned on the III-V structure 900 (e.g., wet and/or dry etched) additional layers of the III-V are grown to on the etchings. In other example embodiments, the grating is a top-surface grating and no further regrowth over the gratings occurs; instead, the bonding surface of the top-surface grating is bonded to the silicon wafer, as discussed in further detail below.

FIG. 9B shows an example etched III-V structure 925 (e.g., or embedded grating upon which epi regrowth has been applied as illustrated in FIG. 9B, or a III-V epitaxial wafer with a top-surface grating where the regrowth is omitted), in accordance with some example embodiments. The etched III-V structure 925 is bonded to the silicon structure (e.g., silicon wafer) to form the bonded structure 950 that includes one or more DFBs having the gratings. In some example embodiments, prior to bonding, a dielectric layer (e.g. SiO2, SiN, or Al2O3) is added to the surface of the etched III-V structure 925 to improve bonding.

In some example embodiments, the etched III-V structure 925 is bonded to the silicon structure using plasma enhanced wafer bonding. For example, (1) a III-V epitaxial wafer is patterned with DFB gratings and alignment marks to align the III-V epitaxial structure on the silicon; (2) the III-V epitaxial wafer is mounted face down on UV release tape and the singulation process is performed on the backside of the III-V epitaxial wafer to protect the frontside surface (e.g., top-surface grating, bonding side) from damage and contamination; and (3) each III-V epitaxial die is accurately bonded to a target SOI using the alignment marks such that the grating and active region is disposed over the narrow width of the silicon waveguide and the tapers of the silicon waveguide are disposed under respect SOA regions of the III-V die.

In some example embodiments, the etched III-V structure 925 is bonded to the silicon structure using micro-Transfer Printing (uTP). For example, (1) a III-V epitaxial wafer is patterned with DFB gratings and alignment marks to align the III-V epitaxial structure on the silicon; (2) the III-V epitaxial wafer is singulated into III-V epitaxial dies using uTP process of etching and undercutting; and (3) each III-V epitaxial die is accurately bonded to a target SOI using the uTP stamp process.

In some example embodiments, the etched III-V structure 925 is then cleaved into small rectangles (e.g., epitaxial dies) using the alignment marks on the etched III-V structure 925 to align cleave locations to the gratings. The etched III-V structure 925 (e.g., an epitaxial die) is then bonded to the SOI structure to form the bonded structure 950. In some example embodiments, the bonded structure 950 is then further processed to form additional circuit components, and vias and metallic pads are integrated into the bonded structure 950 to provide current and drive the symmetric DFB laser.

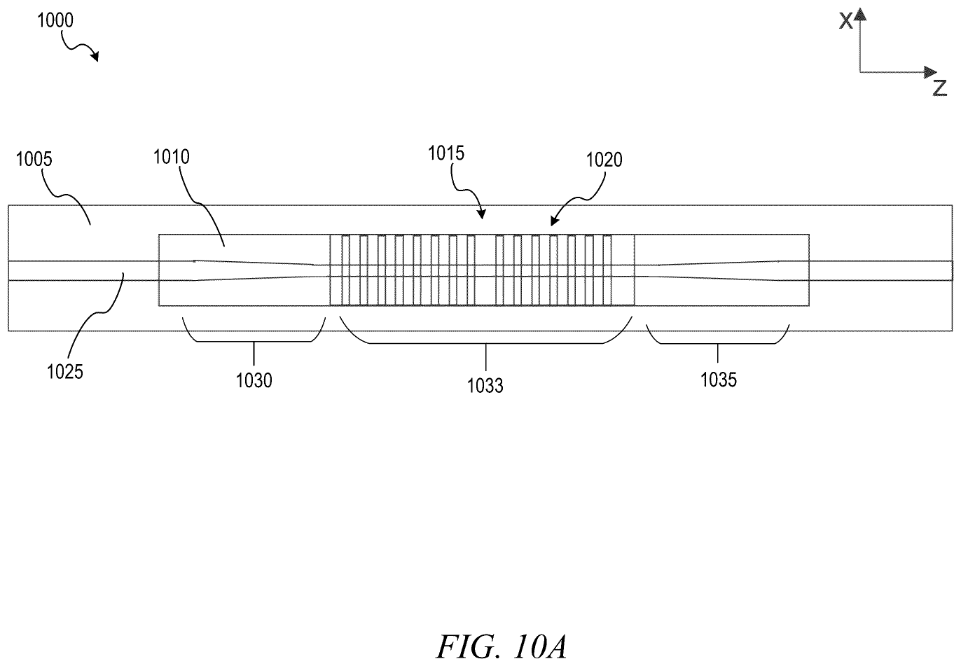

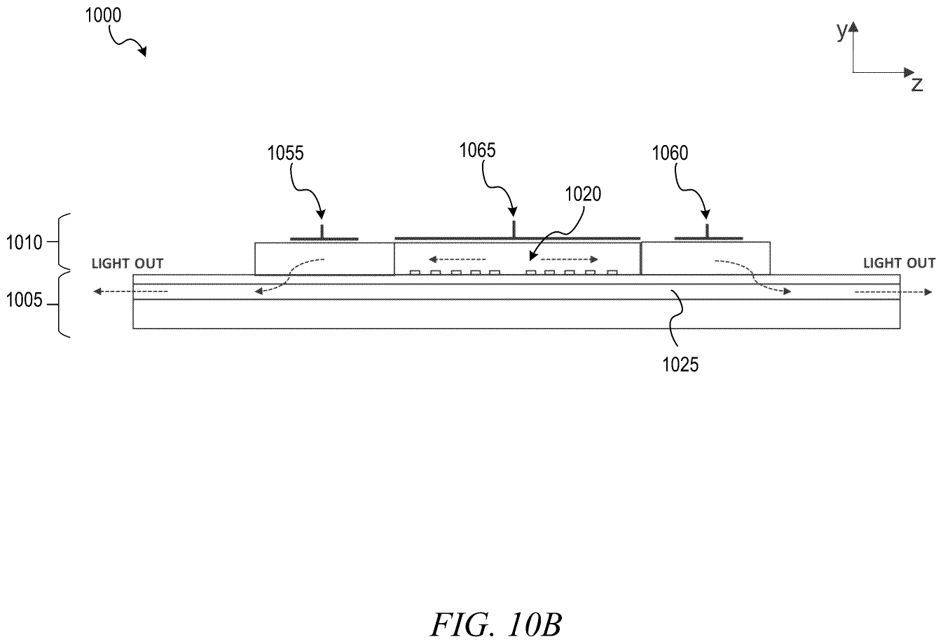

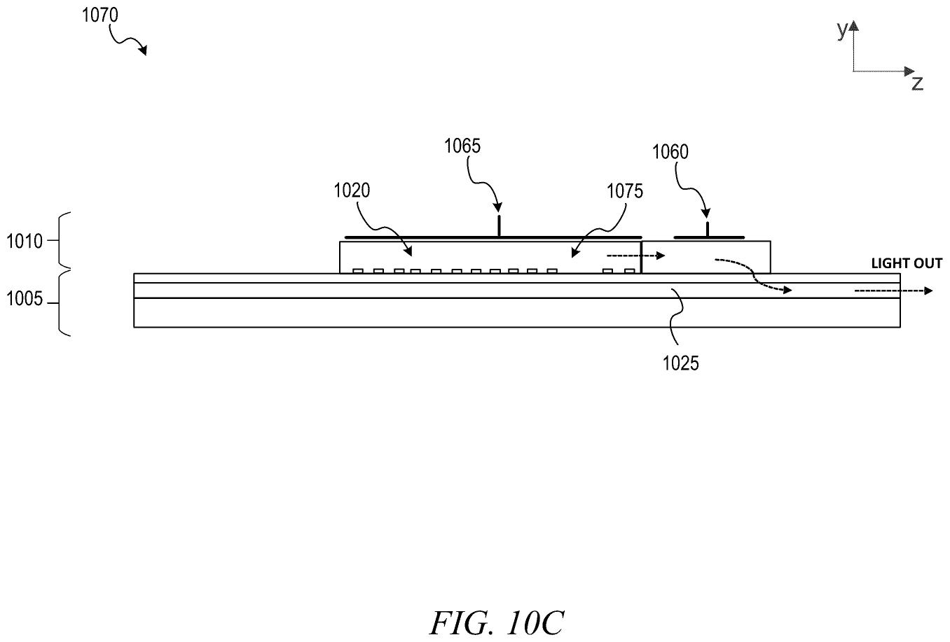

FIG. 10A shows an example DFB laser with integrated III-V gratings 1000, in accordance with some example embodiments. From a top-down perspective (e.g., X and Z dimensions), the III-V structure 1010 (e.g., III-V semiconductor structure, III-V epi die, III-V wafer) is on the silicon structure 1005 (e.g., silicon wafer, SOD, which includes a silicon waveguide 1025 to receive light coupled from the III-V structure 1010. The light is generated via gain material in the active region 1033 of the III-V structure 1010.

In some example embodiments, the light propagates from the active region 1033 to a first SOA region 1030 and a second SOA region 1035, which couple the light from the III-V structure 1010 to the silicon waveguide 1025 of the silicon structure 1005 via tapers in the silicon waveguide 1025 that are formed under the respective first SOA region 1030 and a second SOA region 1035.

The tapered portions of the silicon waveguide 1025 taper to a narrow width section (e.g., taper from 2 um to ˜0.5 um) of the silicon waveguide that extend along the active region 1033 to minimize coupling from the III-V structure 1010 to the silicon structure 1005 along that section. That is, to keep the light in the III-V material so that the mode is completely distributed inside the gain section of the III-V structure 1010 in order to maximize modal gain and power efficiency.

In some example embodiments, the grating 1020 is formed along a longitudinal direction of the active region 1033, and terminates at the first SOA region 1030 and a second SOA region 1035, such that the mode selection of the output light from the active region is completed within the active region 1033 via the grating 1020 (e.g., the grating 1020 provides optical feedback such that multimode light that would otherwise be generated by the gain material is instead generated as two-mode or single mode light). In some example embodiments, the grating 1020 extends outside the active region 1033, e.g., partially into the SOA regions of the III-V layer, to add reflectivity to the cavity or other modify the coupling of the light.

In some example embodiments, a quarter wave shift (QWS) feature 1015 is formed in a middle portion of the grating 1020 (e.g., changing the grating teeth spacing to add a peak) to generate a symmetric cavity to refine the mode selection (e.g., from two-mode light to single mode light, light at a fixed wavelength) to provide light symmetrically from each end of the active region 1033. In some example embodiments, an asymmetric DFB structure can be formed by positioning a QWS feature toward one end of the cavity of the active region 1033. In some example embodiments, the grating is configured as an adiabatic chirped grating or non-uniform grating, which can be configured per a given design to further tailor the mode and power fraction toward one end of the active region 1033. In some example embodiments, the DFB having the grating in the III-V structure is a distributed phase delay DFB. In some example embodiments that implement the symmetric DFB structure (e.g., with a middle QWS feature), a reflector can be integrated in the silicon waveguide 1025 to reflect half of the light from one end port of the silicon waveguide 1025 to the other port in order to maximize output from the other port.

FIG. 10B shows an example DFB laser with integrated III-V gratings 1000, in accordance with some example embodiments. As illustrated from a side perspective (e.g., Y and Z dimensions) and as discussed above, the grating 1020 is formed in the III-V structure 1010 which is then then flipped and bonded to the silicon structure 1005 (e.g., in a flip-chip configuration), in accordance with some example embodiments. Further, a DFB electrode 1065 applies current (e.g., forward bias) to generate the light (e.g., single mode light from a QWS feature in the gratings), and a first SOA electrode 1055 and a second SOA electrode 1060 are configured to further amplify the light, which is then evanescently coupled to the tapered portions of the silicon waveguide 1025. In some example embodiments, the SOA electrodes are partial electrodes or are omitted from the structure 1000.

FIG. 10C shows an example DFB laser 1070 in a asymmetric configuration, in accordance with some example embodiments. As illustrated in FIG. 10C, the grating 1020 is configured with a shift feature 1075 (e.g., QWS) that is disposed towards one end of the DFB laser, such that the light exits from the one side of the DFB laser 1070.

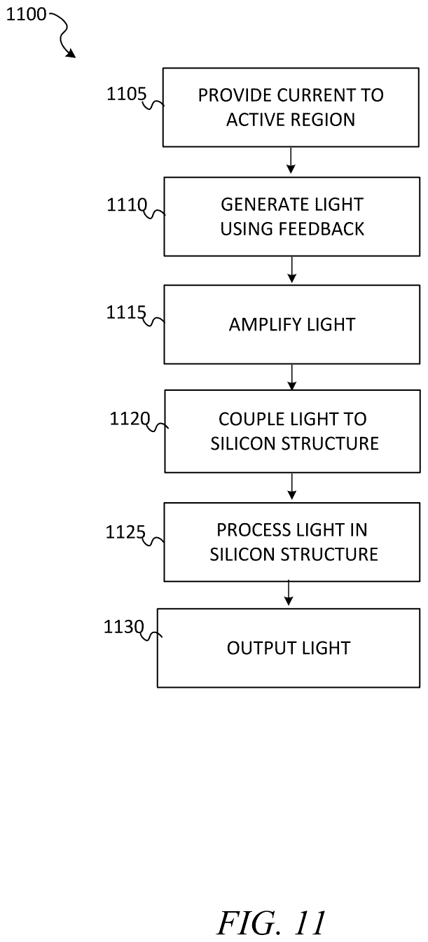

FIG. 11 shows a flow diagram of a method 1100 for implementing a DFB laser having integrated III-V gratings, in accordance with some example embodiments. At operation 1105, the DFB electrode 1065 applies current (e.g., forward bias) to the active region 1033. At operation 1110, due to the current the active region 1033 generates a mode of light using the feedback from the grating (e.g., single mode light from a grating with a QWS in the middle). At operation 1115, one of more SOAs amplify the light. For example, the light from the active region 1033 is output to the first SOA region 1030 and the second SOA region 1035 that amplify the light. At operation 1120, the light is coupled from the SOAs to the silicon structure 1005. The light is evanescently coupled to tapered sections of the silicon waveguide 1025 that are proximate or disposed under the SOA sections. At operation 1125, the light is further processed in the silicon structure 1005. For example, one or more components (e.g., passive silicon components, such as waveguides, couplers, splitters) that are fabricated in the silicon wafer process the light according to a given photonic circuit design (e.g., PIC switch silicon photonic circuitry). At operation 1130, the light is output (e.g., output from the PIC having the III-V integrated grating to a fiber).

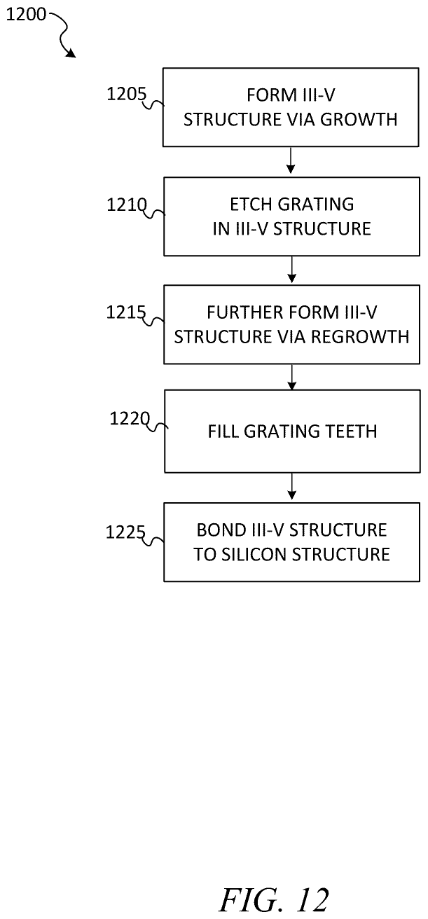

FIG. 12 shows a flow diagram of a method 1200 for forming a DFB laser having integrated III-V gratings, in accordance with some example embodiments. At operation 1205, a III-V structure is formed via growth (e.g., III-V epitaxy growth). At operation 1210, a grating structure is etched into the III-V structure (e.g., wet or dry etching to form a grating, such as a grating with QWS feature). At operation 1215, the III-V structure is further formed via regrowth. In some example embodiments, the grating is a top-grating and the regrowth does not occur (e.g., operation 1215 is omitted). At operation 1220, the teeth of the grating are filled with material, such as a dielectric material, to affect the performance of the DFB (e.g., increased reliability, increase thermal conduction). In some example embodiments, the gratings are air-filled and no further material is applied to fill the teeth (e.g., operation 1220 is omitted). At operation 1225, the III-V structure is bonded to the silicon structure (e.g. flip chip bonded, as illustrated in FIG. 9B).

In view of the disclosure above, various examples are set forth below. It should be noted that one or more features of an example, taken in isolation or combination, should be considered within the disclosure of this application.

The following are example embodiments: Example 1. A photonic integrated circuit distributed feedback laser comprising: a III-V semiconductor structure comprising an active region and a grating etched on a bonding surface of the III-V semiconductor structure to provide optical feedback to the active region to generate output light that is output from a first side of the active region and that is further output from a second side of the active region; and a silicon structure comprising a silicon waveguide to receive the output light from the first side and the second side of the active region of the III-V semiconductor structure, the III-V semiconductor structure bonded to the silicon structure such that the bonding surface having the grating is bonded to a surface of the silicon structure to optically couple the active region to the silicon waveguide.

Example 2. The photonic integrated circuit distributed feedback laser of example 1, wherein the first side and the second side of the active region are separated by the grating that is etched on the bonding surface.

Example 3. The photonic integrated circuit distributed feedback laser of any of examples 1 or 2, wherein the output light is single mode light.

Example 4. The photonic integrated circuit distributed feedback laser of any of examples 1-3, wherein the grating provides optical feedback to generate the single mode light.

Example 5. The photonic integrated circuit distributed feedback laser of any of examples 1-4, wherein the grating is configured to apply a quarter wave shift to the active region to form the output light.

Example 6. The photonic integrated circuit distributed feedback laser of any of examples 1-5, wherein the quarter wave shift of the grating generates single mode light as the output light.

Example 7. The photonic integrated circuit distributed feedback laser of any of examples 1-6, wherein the grating is configured to apply the quarter wave shift in a middle portion of the grating.

Example 8. The photonic integrated circuit distributed feedback laser of any of examples 1-7, wherein the grating is a non-uniform grating that shifts an optical distribution towards one of: the first side of the active region, or the second side of the active region.

Example 9. The photonic integrated circuit distributed feedback laser of any of examples 1-8, wherein the III-V semiconductor structure comprises a first semiconductor optical amplifier to couple light from the first side of the active region to the silicon waveguide.

Example 10. The photonic integrated circuit distributed feedback laser of any of examples 1-9, wherein the III-V semiconductor structure comprises a second semiconductor optical amplifier to couple light from the second side of the active region to the silicon waveguide of the silicon structure.

Example 11. The photonic integrated circuit distributed feedback laser of any of examples 1-10, wherein the silicon waveguide comprises a narrow width section that is proximate to the active region of the III-V semiconductor structure that is bonded to the silicon structure, the narrow width section minimizing coupling from the active region to the narrow width section of the silicon waveguide.

Example 12. The photonic integrated circuit distributed feedback laser of any of examples 1-11, wherein the silicon waveguide comprises one or more widened sections that are wider than the narrow width section to couple the output light from the III-V semiconductor structure to the silicon waveguide.

Example 13. The photonic integrated circuit distributed feedback laser of any of examples 1-12, wherein the output light is coupled from the III-V semiconductor structure to the silicon structure without facet coating the III-V semiconductor structure.

Example 14. The photonic integrated circuit distributed feedback laser of any of examples 1-13, wherein the III-V semiconductor structure is bonded to the silicon structure using plasma based wafer bonding.

Example 15. The photonic integrated circuit distributed feedback laser of any of examples 1-14, wherein the III-V semiconductor structure is bonded to the silicon structure using transfer printing based bonding.

Example 16. The photonic integrated circuit distributed feedback laser of any of examples 1-15, wherein the grating is a top-surface grating and no regrowth of III-V material is applied to the top-surface grating.

Example 17. The photonic integrated circuit distributed feedback laser of any of examples 1-16, wherein grating teeth of the grating are filled with a dielectric material to reduce coupling efficiency.

Example 18. A method for manufacturing a photonic integrated circuit distributed feedback laser comprising: etching a grating on a III-V semiconductor structure, the III-V semiconductor structure comprising an active region to generate light, the grating being etched on a bonding surface of the III-V semiconductor structure to provide optical feedback to the active region to generate output light that is output from a first side of the active region and that is further output from a second side of the active region; and bonding the III-V semiconductor structure to a silicon structure, the silicon structure comprising a silicon waveguide to receive the output light from the III-V semiconductor structure, the III-V semiconductor structure bonded to the silicon structure such that the bonding surface having the grating is bonded to a surface of the silicon structure to optically couple the active region to the silicon waveguide.

Example 19. The method of example 18, wherein the first side and the second side of the active region are separated by the grating that is etched on the bonding surface.

Example 20. The method of any of examples 18 or 19, wherein the grating is etched such that a quarter wave shift is applied to the active region to form the output light.

In the foregoing detailed description, the method and apparatus of the present inventive subject matter have been described with reference to specific exemplary embodiments thereof. It will, however, be evident that various modifications and changes may be made thereto without departing from the broader spirit and scope of the present inventive subject matter. The present specification and figures are accordingly to be regarded as illustrative rather than restrictive.

What is claimed is:

1. A distributed feedback laser comprising:
a III-V semiconductor structure comprising an active region and a grating etched on a bonding surface of the III-V semiconductor structure to provide optical feedback to the active region to generate output light that is output from the active region; and
a silicon structure comprising a silicon waveguide to receive the output light from the first side and the second side of the active region of the III-V semiconductor structure, the III-V semiconductor structure bonded to the silicon structure such that the bonding surface is bonded to a surface of the silicon structure.

2. The distributed feedback laser of claim 1, wherein the distributed feedback laser is an asymmetric distributed feedback laser configured to output the output light from a single side of the active region.

3. The distributed feedback laser of claim 1, wherein the output light is output from a first side of the active region and wherein the output light is further output a second side of the active region that is opposite of the first side.

4. The distributed feedback laser of claim 2, wherein the first side and the second side of the active region are separated by the grating that is etched on the bonding surface.

5. The distributed feedback laser of claim 1, wherein the output light is single mode light.

6. The distributed feedback laser of claim 5, wherein the grating provides optical feedback to generate the single mode light.

7. The distributed feedback laser of claim 1, wherein the grating is configured to apply a quarter wave shift to the active region to form the output light.

8. The distributed feedback laser of claim 7, wherein the quarter wave shift of the grating generates single mode light as the output light.

9. The distributed feedback laser of claim 7, wherein the grating is configured to apply the quarter wave shift in a middle portion of the grating.

10. The distributed feedback laser of claim 1, wherein the grating is a non-uniform grating that shifts an optical distribution towards one of: the first side of the active region, or the second side of the active region.

11. The distributed feedback laser of claim 1, wherein the III-V semiconductor structure comprises a first semiconductor optical amplifier to amplify light from the first side of the active region to the silicon waveguide.

12. The distributed feedback laser of claim 1, further comprising one or more adiabatic couplers, wherein the output light is coupled from at least one or more of the first side or second side using the one or more adiabatic couplers to couple light to the silicon waveguide.

13. The distributed feedback laser of claim 12, wherein the adiabatic coupler comprises a III-V waveguide, the III-V waveguide disposed above the silicon waveguide, and wherein the III-V waveguide and the silicon layer are separated by an oxide layer.

14. The distributed feedback laser of claim 9, wherein the III-V semiconductor structure comprises a second semiconductor optical amplifier to couple light from the second side of the active region to the silicon waveguide of the silicon structure.

15. The distributed feedback laser of claim 1, wherein the silicon waveguide comprises a narrow width section that is proximate to the active region of the III-V semiconductor structure that is bonded to the silicon structure, the narrow width section minimizing coupling from the active region to the narrow width section of the silicon waveguide.

16. The distributed feedback laser of claim 15, wherein the silicon waveguide comprises one or more widened sections that are wider than the narrow width section to couple the output light from the III-V semiconductor structure to the silicon waveguide.

17. The distributed feedback laser of claim 1, wherein the output light is coupled from the III-V semiconductor structure to the silicon structure without facet coating the III-V semiconductor structure.

18. A method for manufacturing a distributed feedback laser comprising:
etching a grating on a III-V semiconductor structure, the III-V semiconductor structure comprising an active region to generate light, the grating being etched on a bonding surface of the III-V semiconductor structure to provide optical feedback to the active region to generate output light that is output from a first side of the active region and that is further output from a second side of the active region; and
bonding the III-V semiconductor structure to a silicon structure, the silicon structure comprising a silicon waveguide to receive the output light from the III-V semiconductor structure, the III-V semiconductor structure bonded to the silicon structure such that the bonding surface having the grating is bonded to a surface of the silicon structure to optically couple the active region to the silicon waveguide.

19. The method of claim 18, wherein the first side and the second side of the active region are separated by the grating that is etched on the bonding surface.

20. The method of claim 18, wherein the grating is etched such that a quarter wave shift is applied to the active region to form the output light.
